(19) United States
(12) Patent Application Publication
(10) Pub. No.: US 2014/0091784 A1
(43) Pub. Date: Apr. 3, 2014

(54) Artificial Defect for Eddy Current Inspection

(71) Applicant: UNITED TECHNOLOGIES CORPORATION, Hartford, CT (US)

(72) Inventors: David A. Raulerson, Palm Beach Garden, FL (US); Kevin D. Smith, Glastonbury, CT (US)

(73) Assignee: United Technologies Corporation, Hartford, CT (US)

(21) Appl. No.: 13/679,571

(22) Filed: Nov. 16, 2012

Related U.S. Application Data
(60) Provisional application No. 61/708,394, filed on Oct. 1, 2012.

(51) Int. Cl. G01R 35/00; H05K 1/02; G01R 33/12

(52) U.S. Cl. CPC G01R 35/005; G01R 33/12; H05K 1/0277
USPC 324/202; 174/254

(57) ABSTRACT

A flex circuit for creating artificial defects uses a thin conductive layer with rectangular slots therein representing defects. A thin insulating over-layer is used to protect the conductive layer as well as an eddy current probe. The flexible circuit is then temporarily attached to the surface of the part or material to be inspected. A feature of the described system is that it is directly scalable to an electric discharge machined (EDM) notch. In an embodiment, a thin conductive layer is used which is scalable to a thicker lower conductive layer like a conventional EDM notch. In this way, a thin conductive artificial defect can electromagnetically represent a thicker albeit less conductive EDM notch. The flexible circuit makes it easier to place multiple notches in complex part geometries, and allows for more accurate relative positioning between slots, e.g., for array and wide coverage probes.

### RELATED APPLICATION

This application is a continuation of and claims priority to U.S. Provisional Application Ser. No. 61/708,394, entitled Artificial Defect For Eddy Current Inspection, filed on Oct. 1, 2012, which application is herein incorporated by reference in its entirety.

### TECHNICAL FIELD

The present disclosure relates to techniques and equipment for identifying defects and, more particularly, to a method and a device for creating an artificial defect for nondestructive eddy current-based defect detection.

### BACKGROUND

It is important in some fields to inspect for and detect surface defects in conductive parts before placing those parts into use or providing such parts for sale. One manner of detecting surface defects is to induce and analyze eddy currents in the surface of interest. In this way, cracks and other defect will show an altered eddy current response, alerting an operator to the defect.

However, in order for eddy current detection of defects to work properly, the eddy current detection sensitivity should be calibrated or verified prior to and after analysis. It is known to machine small notches into parts, e.g., via EDM (electric discharge machining), to simulate defects and allow for calibration or tuning of the eddy current detection system. However, this technique sacrifices a specimen of the part in question. Thus, for expensive parts, the technique may prove prohibitively expensive, and for parts with limited availability, sacrificing a part may not be practical. Moreover, it is sometimes necessary to test a used part and return it to service if no defects are found. In addition, EDM notches can be difficult to form in complex geometries with respect to size and position.

A technique to calibrate eddy detection equipment for surface defect analysis without damaging a specimen is disclosed in U.S. Pat. No. 6,734,664 to Bryson et al. This technique involves placing a conductive strip of material within a sheet of nonconductive nonmagnetic material. The effect of the strip of conductive material during eddy current analysis is calibrated initially by comparison to a known defect, and then thereafter can be used to independently calibrate the eddy current detection response. However, the device may be difficult to reuse after detachment from a given sample, and depending upon the conductive material used, the device may be expensive enough to discourage disposal. Moreover, the presence of the conductive strip of material, while used to correlate the eddy current response to potential defects, does not actually simulate a defect such as a crack.

It will be appreciated that this background section discusses problems and solutions noted by the inventors; the inclusion of any problem or solution in this section is not an indication that the problem or solution represents known prior art except as otherwise expressly noted. With respect to prior art that is expressly noted as such, the inventors' summary thereof above is not intended to alter or supplement the prior art document itself; any discrepancy or difference should be resolved by reference to the prior art document itself. It will be further appreciated that solving the noted problems, while desirable to the inventors, is not a limitation of the appended claims except where expressly noted, since the claimed invention is susceptible to a wide variation in implementation techniques.

### SUMMARY

In accordance with an aspect of the disclosure, a method is provided for calibrating an eddy current defect detection system for a conductive material. The method entails creating a flex circuit having a conductive layer and an insulating layer, with there being one or more slots through the conductive layer. The flex circuit is adhered to a portion of the conductive material and the eddy current defect detection system is calibrated by scanning the adhered flex circuit.

In accordance with another aspect of the disclosure, a test structure is provided for calibrating an eddy current defect detection system. In accordance with this aspect of the disclosure, the test structure includes a conductive material having a material portion and a flex circuit adhered to a surface of the material portion. The flex circuit includes a conductive layer covered by an insulating layer, the conductive layer having one or more slots therethrough.

In accordance with yet another aspect of the disclosure, a flex circuit is provided having an insulating layer as well as a conductive layer, wherein the conductive layer includes a plurality of slots cut therethrough. Each slot is sized to simulate a defect in a surface to which the flex circuit may be applied.

Other features and advantages of various embodiments of the disclosed principles will become apparent from the following detailed description read in conjunction with the appended figures.

### BRIEF DESCRIPTION OF THE DRAWINGS

Embodiments of the invention will be described in greater detail below with reference to the enclosed drawings, wherein:

FIG. 1 is a cross-sectional schematic view of a part portion including an artificial defect formed in the portion;

FIG. 2 is a cross-section schematic view of a part portion including an artificial defect created by overlaying a flexible circuit on the portion;

FIG. 3 is a schematic view of a flex circuit in accordance with an embodiment of the disclosure; and

FIG. 4 is a response plot showing the EC response to an artificial defect created in accordance with an embodiment of the disclosure.

### DESCRIPTION OF EMBODIMENTS

In an embodiment, a test strip having one or more artificial defects formed therein is used as a current calibration standard for eddy current testing, a part coverage specimen, or a POD (Probability of Detection) specimen. This allows the test strip to replace artificial defects formed in the part under test itself. The present invention will be described more fully hereinafter with reference to the accompanying drawings, in which various embodiments are shown. The disclosed principles may, however, be embodied in many different forms and should not be construed as limited to the embodiments set forth herein; rather, these embodiments are provided so that this disclosure will be thorough and complete, and will fully convey the scope of the invention to those skilled in the art. In the drawings, like numbers refer to like elements.

Prior to discussing specific embodiments, certain underlying concepts will be reviewed. The electromagnetic skin depth is the physical characteristic that makes eddy current inspection useful. In particular, the electromagnetic skin depth results in the induced current being confined near the surface of a part being tested. This allows for the detection of cracks and other defects that disrupt or introduce discontinuities into the object surface.

The skin depth depends on the frequency, conductivity and magnetic permeability of the surface under test. Regarding the skin depth, known as δ (skin depth or standard depth of penetration), δ=(πfσμ)^{-1/2} where f is the operating frequency (1/s), σ is the material electrical conductivity (1/ohm m) and μ is the material magnetic permeability (H/m).

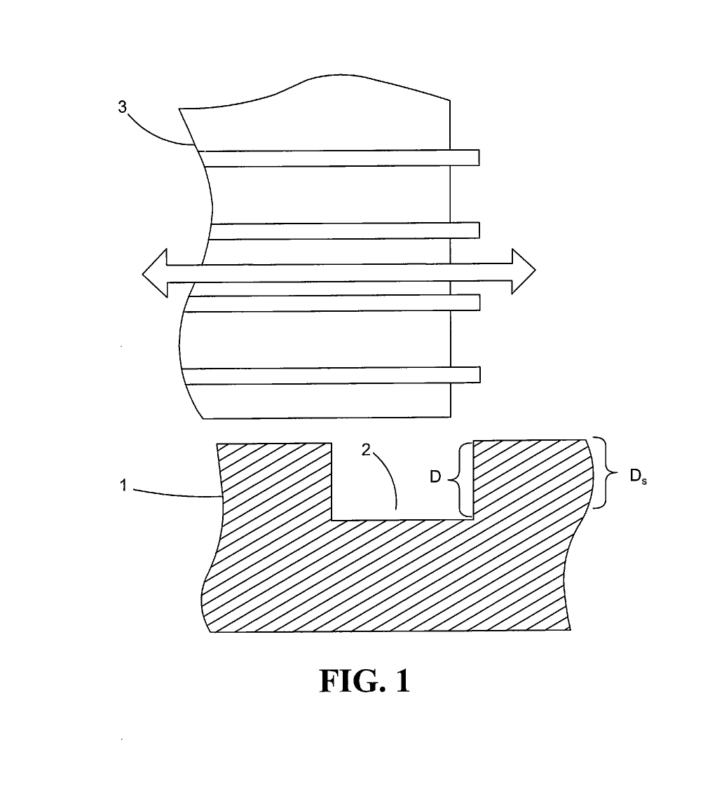

FIG. 1 shows the cross-section of a conventional EDM notch used as an artificial defect. In particular, the figure shows the low conductivity material 1 of the object under test as well as a notch 2 machined in the material of the object. The notch 2 is shown enlarged for clarity, but may have any dimensions, typically based on the flaw size requirements. In addition, the EC probe 3 is shown. As the EC probe 3 is swept across the surface, the characteristics of its driving current are altered by any discontinuities such as notch 2 that may be encountered on the surface.

In order for the EC probe 3 to preferentially detect cracks and other surface defects, it is desirable that the depth D of the notch and the skin depth Dₛ be approximately equal or that the skin depth Dₛ be less than the depth D of the notch. In other words is desirable that the ratio Dₛ/D be about one or less. A number of parameters pertaining to the operation of the EC probe 3 may be adjusted to affect the skin depth and sensitivity of the measurements taken. These include the shape of the EC probe 3, the frequency, voltage, gain or phase of the signal applied to the EC probe 3 to stimulate the eddy current, the speed of the scan, filter settings, and so on.

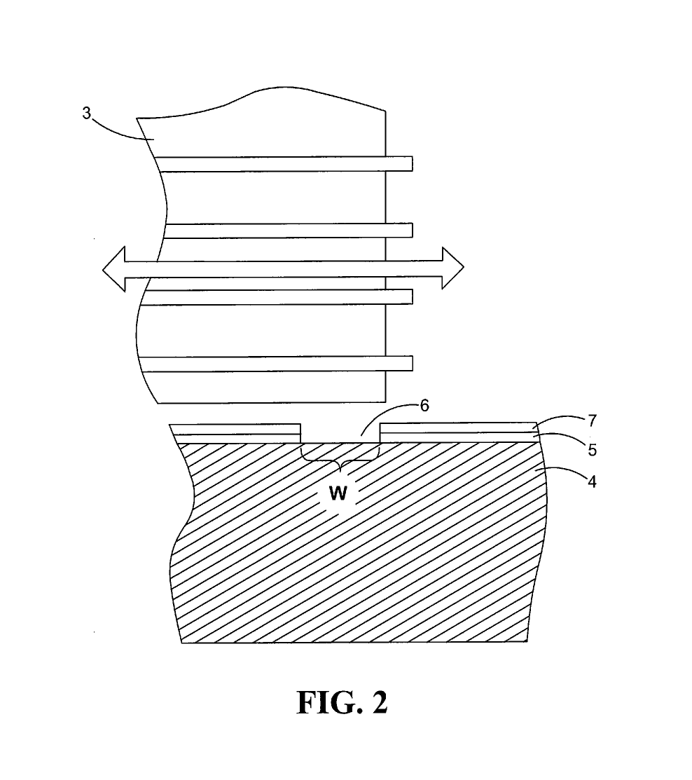

FIG. 2 shows a flex circuit in accordance with an embodiment of the disclosed principles, forming the electromagnetic equivalent of an EDM notch on the surface of a part 4. A flex circuit as referred to herein is a structure having a flexible plastic layer, such as polyimide, PEEK or polyester film adhered to a flexible foil or other conductive layer.

The illustrated flex circuit comprises a first layer 5 of high-conductivity material such as copper, silver, or other high conductivity material. A second layer 7 comprising an insulating material such as polyimide is located adjacent the first layer 5. The thickness of the first layer may be selected based on the notch depth and material conductivities relative to the notch being simulated. In particular, the depth of the flex circuit is determined by the desired simulated notch depth as well as the ratio of the square root of conductivities. In other words, since the first layer 5 is of a high conductivity material such as copper, the skin depth in the first layer 5 is much less than the skin depth in the part under test, which may be made of a lower conductivity material such as titanium, nickel, nickel alloy, and so on. This allows very thin flex circuits to simulate notches in the material under test that would be much deeper than the flex circuit. For example, the first layer 5 may be one mil thick copper and may provide the electromagnetic equivalent of a much deeper notch in the actual material under test.

A slot 6 in the first layer 5 mimics the EDM notch 2 of FIG. 1, but does so nondestructively. The width W and length of the slot may be selected to match the EDM notch being simulated, while the depth is fixed by the thickness of the first layer 5. Multiple flex circuits having different copper layer thicknesses may be used to simulate multiple notch depths. With the flex circuit being simple and cheap, this is an efficient replacement for using EDM notches.

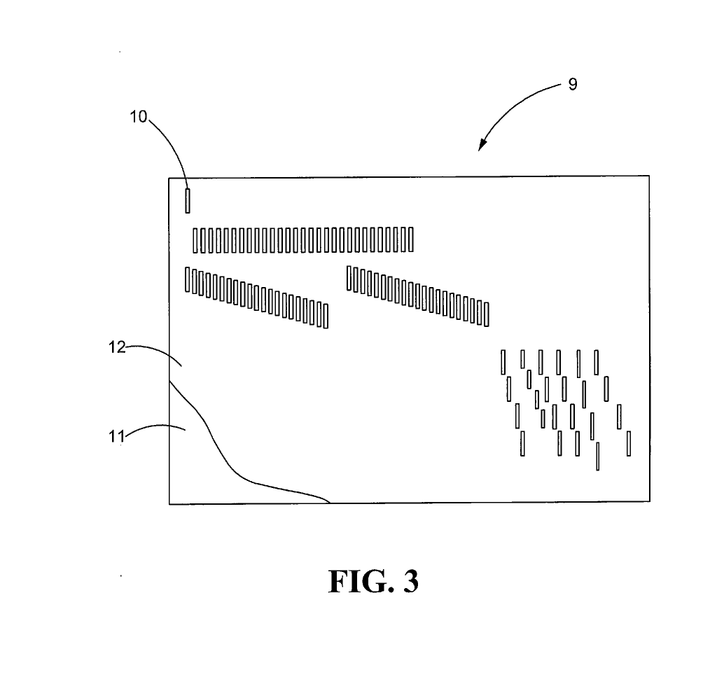

FIG. 3 is a schematic view of a flex circuit 9 according to an embodiment of the disclosed principles. The flex circuit 9 contains an array of slots 10. The slots 10 may be arranged in any desired manner, i.e., singly, in a row, in a two-dimensional arrangement and/or in an arbitrary arrangement. The figure also shows the structure of the flex circuit 9, comprising a conductive layer 11, e.g., copper, topped by a nonconductive layer 12 to protect the circuit 9 as well as to protect the EC probe.

The slots 10 may be formed in the flex circuit 9 is any suitable manner, e.g., via laser cutting, etching, or other suitable tool or technique. The slots 10 may extend only through the conductive layer 11, but this is not required. In an embodiment, the slots 10 extend through both the conductive layer 11 and the nonconductive layer 12. Furthermore, an additional layer, not shown, may be included. For example, in an embodiment, the flex circuit 9 is taped to an object to be tested, with the tape forming a further layer in addition to those shown.

The slots 10 may be of the same or different sizes, e.g., the same or different lengths, widths and depths. For example, in order to simulate a range of crack or defect sizes and to be able to tune the EC probe to detect the entire range of sizes, a flex circuit having a range of slot sizes may be applied to the part under test.

As noted above, the thickness of the conductive layer 11 is typically constant for a given flex circuit, such that different flex circuits are used to simulate different slot depths. However, in an embodiment, the thickness of the conductive layer in a flex circuit is varied across the flex circuit so that the same flex circuit may be used to simulate differing slot depths as well as differing slot lengths and widths.

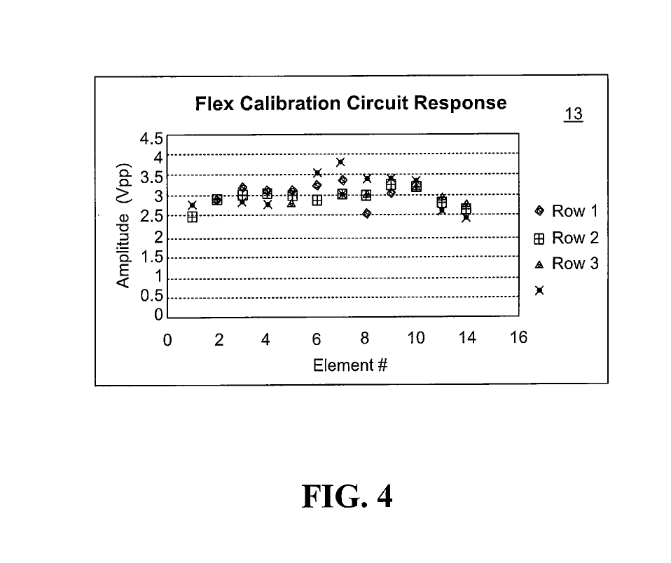

FIG. 4 is a response plot showing the EC response to an artificial defect created in accordance with an embodiment of the disclosure. The plot 13 shows the amplitude response in a standard coordinate system, showing the amplitude (voltage peak-to-peak) on the y-axis and showing the element number on the x-axis. Each row on the flex circuit is plotted using a distinguishable key so that the scans of the different rows may be distinguished.

In practice, the flexible circuit (conductive layer, insulator) is temporarily attached (by adhesive or tape) to the surface of the part to be inspected. It may alternatively be more permanently attached via adhesive, tape, epoxy, etc., such as to create a dedicated calibration standard, coverage, or POD specimen.

As noted above, one useful feature of the described system in an embodiment is that the slots in the flex circuit are directly scalable to an EDM notch. In particular, the thin conductive layer is scalable to a thicker lower conductivity layer like a conventional EDM notch. In this way, a thin conductive artificial defect can electromagnetically represent a thicker albeit less conductive EDM notch. Similarly, a thicker artificial defect made in a lower conductivity material can mimic a defect in a higher conductivity material. Not only does this scalability provide a savings in material costs, but it also allows the flex circuit to be very flexible to conform to the shape of various surfaces having varying degrees of curvature.

This type of artificial defect is inexpensive to manufacture and can be easily modified in its parameters (length, width, thickness, conductivity, etc.) as mentioned above. The implementation is also more representative of the conventional defect response since it entails a large conductive volume and a small defect. It also makes it easier to place multiple notches in complex part geometries compared to EDM, and allows for more accurate relative positioning between slots, as required for array and wide coverage probes.

Moreover, when using EDM notches, which require creating scrap parts for test, coverage, POD and calibration specimens, the cost of scrapping parts is relatively high. In contrast, there is no need to discard parts analyzed via the flex circuit described herein because the defect is placed on rather than into the part.

As noted above, there are several different scenarios in which the flex circuit may be used. One use is calibration in the manner described above, i.e., the slotted flex circuit is applied to a portion of a part to be tested, and the covered area is scanned by the EC probe. With the known slots simulating known defects, the amplitude response of the EC probe is tuned until the artificial defects (slots) are well-detected.

Another usage scenario for the flex circuits is to produce coverage detectors. In this use, the known slots are located at the edges of an area of interest when applied to the portion of the part under test. When the EC probe is scanned over the area, the detection of the known slots at the edges of the area of interest can be used to ensure that the entire area of interest is being covered by the probe.

A third usage scenario for the flex circuit involves the creation of POD measurements. In this scenario, a known distribution of artificial defect sizes are calibrated to actual defect sizes and an EC probe of the array of artificial defects is made to demonstrate that all desired sizes of defect will be detected. In addition to different lengths and widths in the artificial defects, it may be desirable when creating a POD measurement to utilize different flex circuit conductive layer thicknesses as well to simulate different notch depths. As noted above, this may be accomplished via the use of different flex circuits having different conductive layer thicknesses or may be accomplished via a single flex circuit having a gradient of thickness in the conductive layer.

In the drawings and specification, there have been disclosed preferred embodiments and examples of the invention and, although specific terms are employed, they are used in a generic and descriptive sense only and not for the purpose of limitation, the scope of the invention being set forth in the following claims.

1. A method of calibrating an eddy current defect detection system for a conductive material comprising:
creating a flex circuit having a conductive layer and an insulating layer, and one or more slots through the conductive layer;
adhering the flex circuit to a portion of the conductive material; and
calibrating the eddy current defect detection system by scanning the adhered flex circuit.

2. The method of calibrating an eddy current defect detection system for a conductive material according to claim 1, wherein the one or more slots through the conductive layer also extend through the insulating layer.

3. The method of calibrating an eddy current defect detection system for a conductive material according to claim 1, wherein the one or more slots through the conductive layer extend only through the conductive layer.

4. The method of calibrating an eddy current defect detection system for a conductive material according to claim 1, wherein the conductive layer is a copper layer.

5. The method of calibrating an eddy current defect detection system for a conductive material according to claim 1, wherein the one or more slots through the conductive layer are sized to simulate an electromagnetic response similar to a notch in a surface of the conductive material.

6. The method of calibrating an eddy current defect detection system for a conductive material according to claim 1, wherein the one or more slots comprise multiple slots of different sizes.

7. The method of calibrating an eddy current defect detection system for a conductive material according to claim 1, wherein the conductive layer is comprised of a material that has a higher conductivity than the conductive material.

8. A test structure for calibrating an eddy current defect detection system, the test structure comprising:
a conductive material having a material portion; and
a flex circuit adhered to a surface of the material portion, the flex circuit comprising a conductive layer covered by an insulating layer, the conductive layer having one or more slots therethrough.

9. The test structure according to claim 8, wherein the dimensions of the one or more slots are selected such that the eddy current response of a slot is similar to the eddy current response of a machined notch.

10. The test structure for calibrating an eddy current defect detection system according to claim 8, wherein the one or more slots through the conductive layer also extend through the insulating layer.

11. The test structure for calibrating an eddy current defect detection system according to claim 8, wherein the one or more slots through the conductive layer extend only through the conductive layer.

12. The test structure for calibrating an eddy current defect detection system according to claim 8, wherein the conductive layer is a copper layer.

13. The test structure for calibrating an eddy current defect detection system according to claim 8, wherein the one or more slots through the conductive layer are sized to simulate an electromagnetic response similar to a notch in a surface of the portion of the conductive material.

14. The test structure for calibrating an eddy current defect detection system according to claim 8, wherein the one or more slots comprise multiple slots of different sizes.

15. The test structure for calibrating an eddy current defect detection system according to claim 8, wherein the conductive layer is comprised of a material that has a higher conductivity than the conductive material.

16. A flex circuit comprising:
an insulating layer; and
a conductive layer, the conductive layer having a plurality of slots cut therethrough, each slot being sized to simulate a defect in a surface to which the flex circuit may be applied.

17. The flex circuit according to claim 16, wherein the plurality of slots extend through the insulating layer.

18. The flex circuit according to claim 16, wherein the plurality of slots do not extend through the insulating layer.

19. The flex circuit according to claim 16, wherein the conductive layer comprises copper.

20. The flex circuit according to claim 16, wherein the insulating layer comprises polyimide.
